(19) United States
(12) Patent Application Publication
(10) Pub. No.: US 2008/0238302 A1
(43) Pub. Date: Oct. 2, 2008

(54) DISPLAY DEVICE AND METHOD FOR MANUFACTURING THE SAME

(75) Inventors: Un-Cheol SUNG, Anyang-si (KR); Sang-Pil LEE, Seoul (KR); Jung-Yeon KIM, Hwaseong-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/946,241

(22) Filed: Nov. 28, 2007

(30) Foreign Application Priority Data
Mar. 28, 2007 (KR) 10-2007-0030352

(51) Int. Cl. H01L 27/32; H01J 9/02

(52) U.S. Cl. 313/504; 445/25

(57) ABSTRACT

A display device includes a display panel including an organic light emitting diode, a sealing metal foil covering a side of the display panel on which the organic light emitting diode is disposed, and a sealant between the display panel and the sealing metal foil.

### CROSS-REFERENCE TO RELATED APPLICATION

This application claims priority from and the benefit of Korean Patent Application No. 10-2007-0030352, filed on Mar. 28, 2007, which is hereby incorporated by reference for all purposes as if fully set forth herein.

### BACKGROUND OF THE INVENTION

1. Field of the Invention

The present invention relates to a display device and a manufacturing method thereof, and more particularly, to a display device having a slim size, and a manufacturing method thereof.

2. Discussion of the Background

Among the various types of display devices, the liquid crystal display (LCD) and the organic light emitting diode (OLED) display are small and light-weight and have improved in performance due in part to rapidly developing semiconductor technology. This is especially true of the organic light emitting diode display.

An organic light emitting diode display may include a display panel having a thin film transistor (TFT) and an organic light emitting diode and an encapsulation panel facing and covering the display panel. However, the encapsulation panel of a conventional organic light emitting diode display is made of glass. The thickness of the encapsulation panel may be about 700 μm to 1000 μm and that is very thick. Accordingly, the encapsulation panel increases the size of the organic light emitting diode display and it therefore, may be difficult to provide a slim organic light emitting diode display.

### SUMMARY OF THE INVENTION

The present invention provides a slim display device.

The present invention also provides a method of manufacturing the slim display device.

Additional features of the invention will be set forth in the description which follows, and in part will be obvious from the description, or may be learned by practice of the present invention.

The present invention discloses a display device including a display panel including an organic light emitting diode, a sealing metal foil to cover a side of the display panel on which the organic light emitting diode is formed, and a sealant between the display panel and the sealing metal foil.

The present invention also discloses a method of manufacturing a display device including preparing a display panel including an organic light emitting diode (OLED), coating a sealant on the organic light emitting diode of the display panel, covering the sealant with a thin metal plate, and forming a sealing metal foil to cover the organic light emitting diode by cutting the thin metal plate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a cross-sectional view of a display device according to a first exemplary embodiment of the present invention.

FIG. 2 is an enlarged view of a display panel in FIG. 1.

FIG. 3, FIG. 4, and FIG. 5 are cross-sectional views showing a process of manufacturing the display device of FIG. 1.

FIG. 6 is a cross-sectional view of a process of manufacturing a display device according to a second exemplary embodiment of the present invention.

FIG. 7 is a cross-sectional view of a display device according to a third exemplary embodiment of the present invention.

FIG. 8 is a cross-sectional view of a display device according to a fourth exemplary embodiment of the present invention.

FIG. 9 and FIG. 10 are cross-sectional views showing a process of manufacturing the display device of FIG. 8.

FIG. 11 is a cross-sectional view of a display device according to a fifth exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

The accompanying drawings show an organic light emitting diode (OLED) display as a display device.

In addition, the accompanying drawings show an active matrix (AM)-type OLED having a 2Tr-1Cap structure in which one pixel may include two thin film transistors (TFTs) and one capacitor, but it is not limited thereto. Herein, the pixel is a minimum unit used to display an image.

Therefore, in the display device, one pixel may include more than three TFTs and more than two capacitors, and additional wiring may be further provided.

Constituent elements having the same structures throughout the embodiments are denoted by the same reference numerals and are described in a first embodiment. In the other embodiments, only the constituent elements other than the same constituent elements will be described.

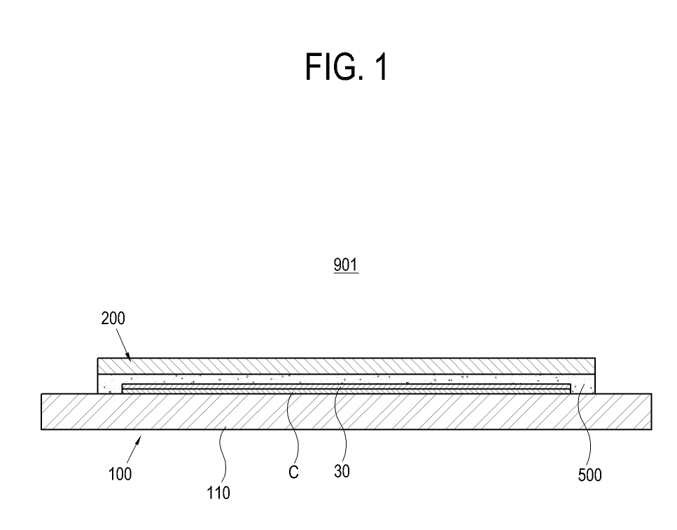

FIG. 1 is a cross-sectional view of a display device according to a first exemplary embodiment of the present invention.

As shown in FIG. 1, a display device 901 includes a display panel 100, a sealing metal foil 200, and a sealant 500. The sealant 500 is filled between the display panel 100 and the sealing metal foil 200 and joins the sealing metal foil 200 to the display panel 100.

The display panel 100 includes a substrate member 110, a circuit-forming layer C formed on the substrate member 110, and an organic light emitting diode 30.

The substrate member 110 may be an insulating substrate, which may be made of glass, crystal, ceramic, or plastic. When the substrate member 110 is made of a material having flexibility, the utilization range of the display device 901 may be increased so that the availability of the display device 901 may be improved.

Although it is not shown in FIG. 1, the circuit-forming layer C may include various thin wires such as a gate line, a data line, a common line, a thin film transistor connected to the thin wire, and a capacitor.

Although it is also not shown in FIG. 1, the organic light emitting diode 30 may include a positive electrode connected to the thin film transistor of the circuit-forming layer C, an organic layer formed on the positive electrode, and a negative electrode formed on the organic layer. The positive electrode may serve as a hole injection electrode. The negative electrode may serve as an electron injection electrode.

Holes and electrons may be injected into the organic layer from the positive electrode and the negative electrode, respectively. The injected holes and electrons form excitons. When the energy state of excitons changes from an excited state to a ground state, light is emitted.

The sealing metal foil 200 covers the display panel 100. That is, the sealing metal foil 200 covers the organic light emitting diode 30 formed on the display panel 100. The sealing metal foil 200 may protect the organic light emitting diode 30 of the display panel 100 and may prevent moisture from permeating the organic light emitting diode 30. The area of the sealing metal foil 200 is substantially equal to or smaller than the area of the display panel 100 and larger than the area of the organic light emitting diode 30.

The sealing metal foil 200 may be made of a metal containing at least one of stainless steel, aluminum (Al), copper (Cu), molybdenum (Mo), silver (Ag), tantalum (Ta), tungsten (W), and titanium (Ti). That is, the sealing metal foil 200 may be made of a metal that has excellent moisture-proofing properties and may be etched easily by etchant.

The sealing metal foil 200 may have a thickness of 5 μm to 500 μm. If the thickness of the sealing metal foil 200 is smaller than 5 μm, a part of the sealing metal foil 200 may be damaged or removed. On the other hand, if the thickness of the sealing metal foil 200 is larger than 500 μm, the total thickness and weight of the display device 901 may increase and the process of manufacturing the display device 901 may become difficult.

With the above-described configuration, the total size of the display device 901 may be minimized. That is, the thin sealing metal foil 200 may prevent moisture from permeating the organic light emitting diode 30. Accordingly, the display device 901 may be slim. Also, the cost of the display device 901 may decrease and productivity may improve.

A conventional organic light emitting diode has an encapsulation panel which is made of glass. The encapsulation panel which is made of glass has a thickness of about 700 μm to 1000 μm. If the encapsulation panel has a thickness of less than 500 μm, the encapsulation panel may not have sufficient strength and stability. Additionally the sealing metal foil 200 is about 10 times cheaper than the encapsulation panel which is made of glass and it results in low production cost.

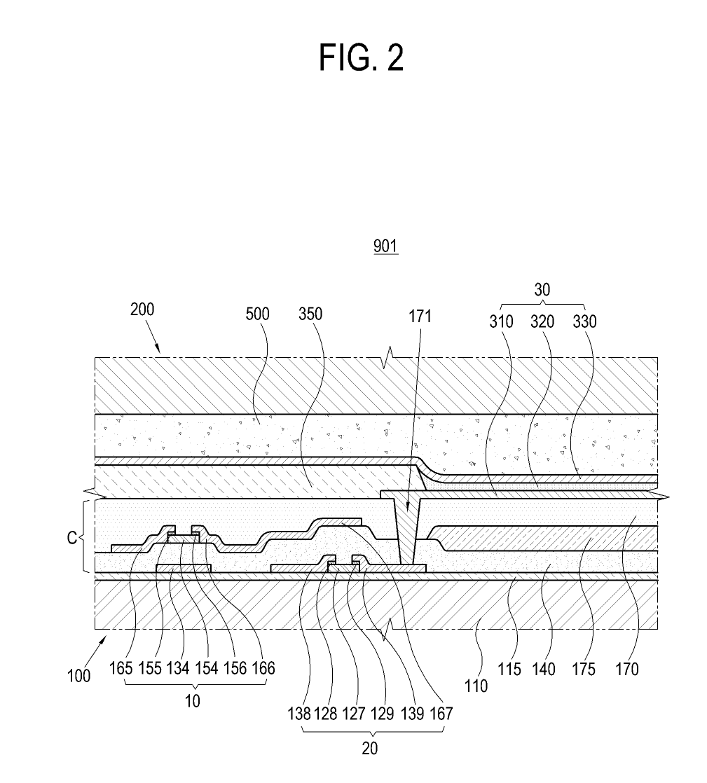

A structure of the display device 901 will be described in further detail with reference to FIG. 2. FIG. 2 shows an enlarged portion of the display device 901, which emits light to display an image.

The display panel 100 displays an image through a plurality of pixels. The pixel is a minimum unit used to display an image. A switching thin film transistor 10, a driving thin film transistor 20, a capacitor (not shown), and an organic light emitting diode 30 may be formed in one pixel.

Although it is not shown in the drawings, the display panel 100 may further include a gate line extending in one direction, a data line crossing the gate line, and a common power line.

The organic light emitting diode 30 may include a pixel electrode 310, an organic layer 320 formed on the pixel electrode 310, and a common electrode 330 formed on the organic layer 320. Herein, the pixel electrode 310 may serve as a hole injection electrode (i.e., positive electrode) and the common electrode 330 may serve as an electron injection electrode (i.e., negative electrode).

The switching thin film transistor 10 may include a switching gate electrode 134, a switching source electrode 165, a switching drain electrode 166, and a switching semiconductor layer 154. The driving thin film transistor 20 may include a driving gate electrode 167, a driving source electrode 138, a driving drain electrode 139, and a driving semiconductor layer 127.

The switching thin film transistor 10 is used as a switching element to select a pixel to emit light. The switching gate electrode 134 is branched from the gate line. The switching source electrode 165 is branched from the data line. The switching drain electrode 166 may be independently disposed and connected to the driving gate electrode 167.

The driving thin film transistor 20 applies a driving power to the pixel electrode 310 to emit light from a selected organic light emitting diode 30 of the organic layer 320.

The driving source electrode 139 of the driving thin film transistor 20 may be branched from a common power line (not shown). The driving drain electrode 139 is connected to the pixel electrode 310 of the organic light emitting diode 30. The pixel electrode 310 is connected to the driving drain electrode 139 through the contact hole 171.

Although it is not shown in the drawings, a pair of storage electrodes may be respectively connected to the common power line and the driving gate electrode 167 and may overlap each other to form a capacitor.

With the above-described configuration, the switching thin film transistor 10 may be driven by a gate voltage supplied through the gate line and supplies a data voltage to the driving thin film transistor 20. A voltage corresponding to the difference between the common voltage, which is supplied by the common power line to the driving thin film transistor 20, and the data voltage, which is supplied by the switching thin film transistor 10, is stored in the capacitor (not shown). A current corresponding to the voltage stored in the capacitor (not shown) flows into the organic light emitting diode 30 through the driving thin film transistor 20 to emit light.

Hereinafter, the display panel 100 will be described with regard to its lamination order.

A buffer layer 115 may formed on the substrate member 110. Herein, the buffer layer 115 may prevent an impurity of the substrate member 110 from penetrating therethrough and provides a planar surface. In other exemplary embodiments, the buffer layer 115 may be omitted.

The driving semiconductor layer 127 may be formed on the buffer layer 115 and may be made of polysilicon.

The switching gate electrode 134, the driving source electrode 138, and the driving drain electrode 139 are formed on the buffer layer 115 and the driving semiconductor layer 127. At least a portion of the driving source electrode 138 and at least a portion of the driving drain electrode 139 may overlap the driving semiconductor layer 127.

Driving ohmic contact layers 128 and 129 may be interposed between the driving semiconductor layer 127 and the driving source electrode 138 and between the driving semiconductor layer 127 and the driving drain electrode 139, respectively. The driving ohmic contact layers 128 and 129 include n+ polysilicon in which an n-type impurity is highly doped. The driving ohmic contact layers 128 and 129 may reduce the contact resistance between the driving semiconductor layer 127 and the driving source electrode 138 and between the driving semiconductor layer 127 and the driving drain electrode 139, respectively.

An insulating layer 140 may be formed on the switching gate electrode 134, the driving source electrode 138, and the driving drain electrode 139. The switching semiconductor layer 154 may be formed on the insulating layer 140 and include an amorphous silicon layer.

The switching source electrode 165 and the switching drain electrode 166 may be formed on the insulating layer 140 and the switching semiconductor layer 154, and the driving gate electrode 167 may be formed on the insulating layer 140. Herein, the driving gate electrode 167 may be connected to the switching drain electrode 166. At least a portion of the switching source electrode 165 and at least a portion of the switching drain electrode 166 may overlap the switching semiconductor layer 154.

In addition, switching ohmic contact layers 155 and 156 may be interposed between the switching semiconductor layer 154 and the switching source electrode 165 and between the switching semiconductor layer 154 and the switching drain electrode 166, respectively. The switching ohmic contact layers 155 and 156 may include n+ amorphous silicon in which an n-type impurity is highly doped. The switching ohmic contact layers 155 and 156 may reduce the contact resistance between the switching semiconductor layer 154 and the switching source electrode 165 and between the switching semiconductor layer 154 and the switching drain electrode 166, respectively.

A passivation layer 170 may be formed on the switching source electrode 165, the switching drain electrode 166, and the driving gate electrode 167. The passivation layer 170 may act as a planarization layer.

The passivation layer 170 may be formed with a contact hole 171 exposing the driving drain electrode 139. The insulating layer 140 may be removed in the contact hole 171.

A pixel electrode 310 may be formed on the passivation layer 170 and may be connected to the driving drain electrode 139 through the contact hole 171.

The pixel electrode 310 may be formed of a transparent conductive material such as indium tin oxide (ITO) or indium zinc oxide (IZO).

A pixel definition layer 350 may be formed on the pixel electrode 310. The pixel definition layer 350 may include an opening exposing the pixel electrode 310. That is, the pixel definition layer 350 may substantially define each pixel in the display device 100.

An organic layer 320 may be formed on the portion of the pixel electrode 310 exposed by the opening of the pixel definition layer 350. The common electrode 330 covers the pixel definition layer 350 and the organic layer 320. The pixel electrode 310, the organic layer 320, and the common electrode 330 form the organic light emitting diode 30.

The organic layer 320 may include a low molecular weight organic material or a polymer material. The organic layer 320 may have multiple layers including a hole-injection layer (HIL), a hole-transporting layer (HTL), an emission layer, an electron-transporting layer (ETL), and an electron-injection layer (EIL). That is, the HIL may be disposed on the pixel electrode 310, which is a positive electrode, and the HTL, the emission layer, the ETL, and the EIL may be sequentially stacked on the HIL.

The emission layer emits light. In a first exemplary embodiment of the present invention, the display device 901 may further include a color filter 175 disposed under the passivation layer 170 and overlapping the organic layer 320. Accordingly, the light emitted from the organic layer 320 has a color. In each pixel, a color filter 175 having one of red, blue, and green colors is disposed, but the color filter 175 is not limited thereto. Accordingly, the color filter 175 may include more than one color. Also, a white pixel may be formed if a portion of the plurality of the organic layer 320 does not overlap the color filter 175.

In other exemplary embodiment, the color filter may be omitted, and the emission layer may emit one of white light, red light, blue light, and green light.

In the first exemplary embodiment, the pixel electrode 310 is the positive electrode and the common electrode 330 is the negative electrode, but they are not limited thereto. That is, the pixel electrode 310 may be the negative electrode and the common electrode 330 may be the positive electrode. In this case, the organic layer 320 may be formed by sequentially stacking the EIL, the ETL, the emission layer, the HTL, and the HIL on the pixel electrode 310.

In the first exemplary embodiment, the thin film transistors 10 and 20 are not limited to above-described structure. The thin film transistors 10 and 20 may have various structures different from the above-described structure.

The sealant 500 may be coated on the common electrode 330 of the display panel 100, and the sealing metal foil 200 may be formed on the sealant 500.

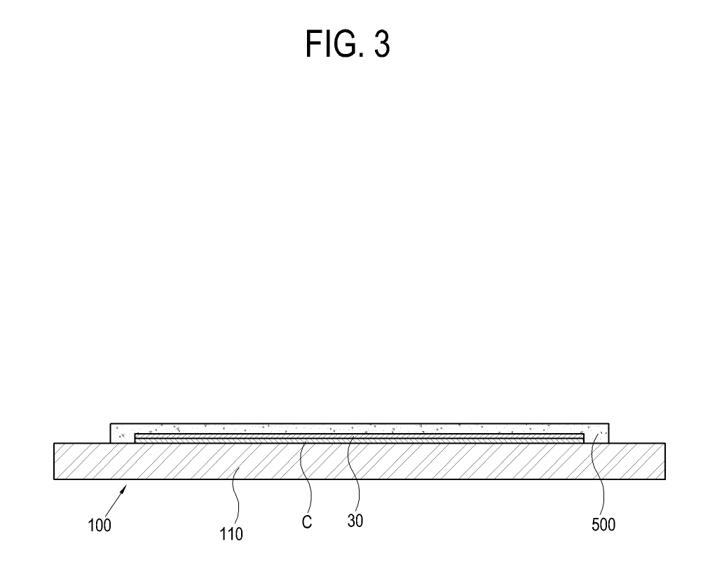

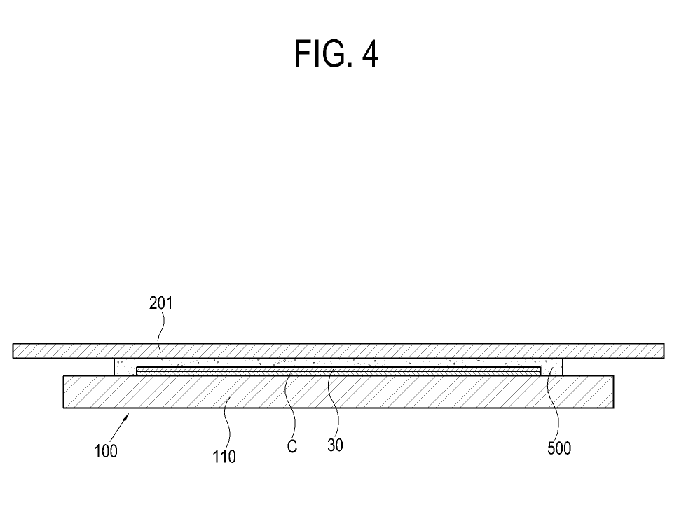

A manufacturing method of the display device 901 according to the first exemplary embodiment of the present invention will be described in further detail with reference to FIG. 3, FIG. 4, and FIG. 5.

As shown in FIG. 3, the display panel 100 including the organic light emitting diode 30 is prepared. Then, the sealant 500 may be coated on the organic light emitting diode 30. Herein, the sealant 500 may be an adhesive filler.

As shown in FIG. 4, the sealant 500 may be covered with a thin metal plate 201. The thin metal plate 201 may include a metal containing at least one of stainless steel, aluminum (Al), copper (Cu), molybdenum (Mo), silver (Ag), tantalum (Ta), tungsten (W), and titanium (Ti).

The thin metal plate 201 is larger than the display panel 100. Accordingly, a single thin metal plate 201 may cover a plurality of display panels 100 that are evenly arranged.

As shown in FIG. 5, the thin metal plate 201 may be cut by an etchant 205 to an adequate size to form the sealing metal foil 200. Here, the size of the sealing metal foil 200 may be substantially equal to or smaller than the size of the display panel 100. However, the size of the formed sealing metal foil 200 may be substantially larger than the size of the organic light emitting diode 30. That is, the sealing metal foil 200 may stably cover the organic light emitting diode 30. The etchant 205 may have a high etch rate for the metal of the thin metal plate 201.

The etchant 205 may be coated along a cutting line (etching place) of the thin metal plate 201 using a dispensing method or a screen printing method. The thin metal plate 201 may be cut along the cutting line through an etching process to form the sealing metal foil 200, and then the display device 901 is cleaned.

With the above-described manufacturing method, a slim display device 901 may be produced.

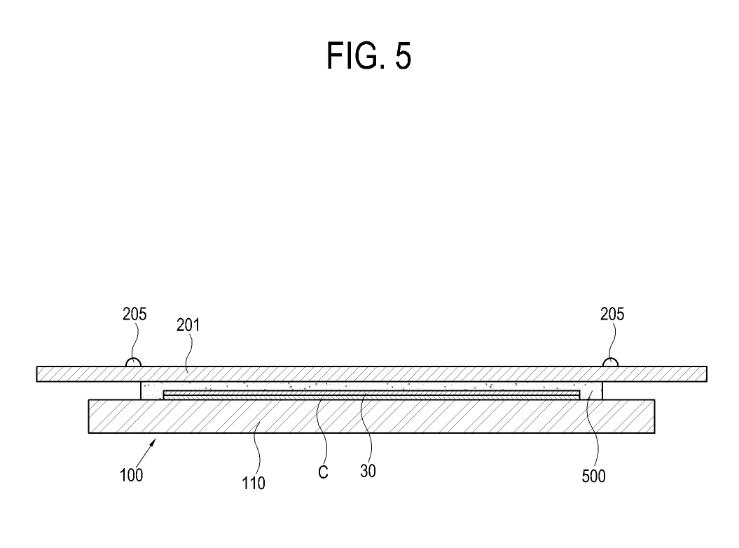

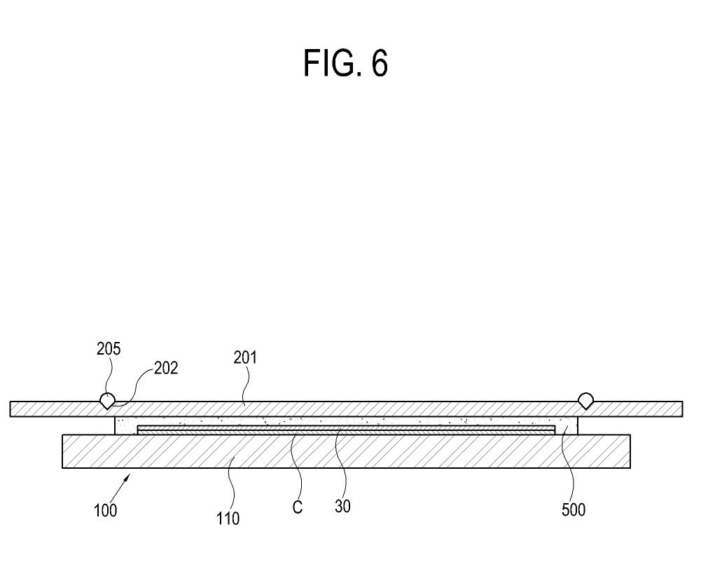

A manufacturing method of the display device according to the second exemplary embodiment of the present invention will be described in detail with reference to FIG. 6.

As shown in FIG. 6, a sealant 500 disposed on a display panel 100 may be covered with a thin metal plate 201. Then, a guide groove 202 may be formed on an etching place of the thin metal plate 201. An etchant 205 may be coated on the guide groove 202, and the thin metal plate 201 may be cut. Accordingly, the thin metal plate 201 may be accurately cut by the etchant 205 and the sealing metal foil 200 may be effectively formed. In another exemplary embodiment, the guide groove may be formed in the thin metal plate 201 before the thin metal plate 201 covers the display panel 100.

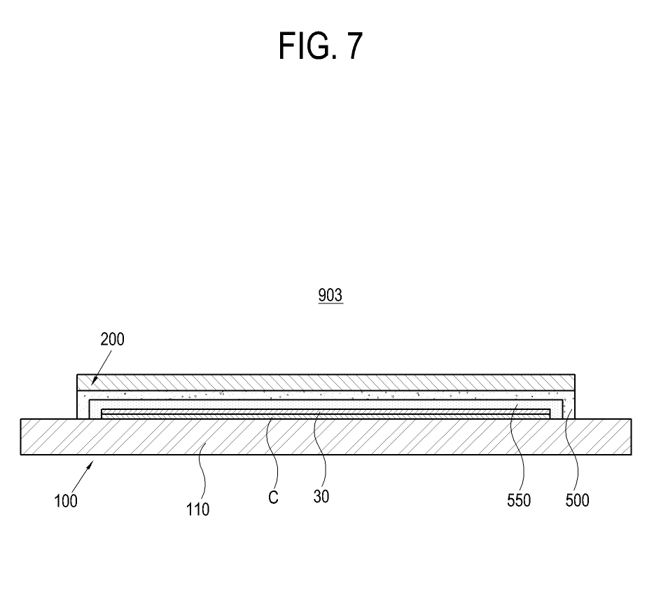

Referring to FIG. 7, the third exemplary embodiment of the present invention will be described.

As shown in FIG. 7, the display device 903 further includes an overcoat layer 550 interposed between an organic light emitting diode 30 of a display panel 100 and a sealant 500. Herein, the overcoat layer 550 may include an inorganic material such as silicon nitride, silicon oxide, or the others.

With the above-described configuration, the overcoat layer 550 may prevent damage to the organic light emitting diode 30 during the coating of the sealant 500 on the organic emitting diode 30 and the forming of the sealing metal foil 200. Also, the overcoat layer 550 may prevent the etchant from permeating the organic light emitting diode 30. Accordingly, the display device 903 having a slim size may be stably made.

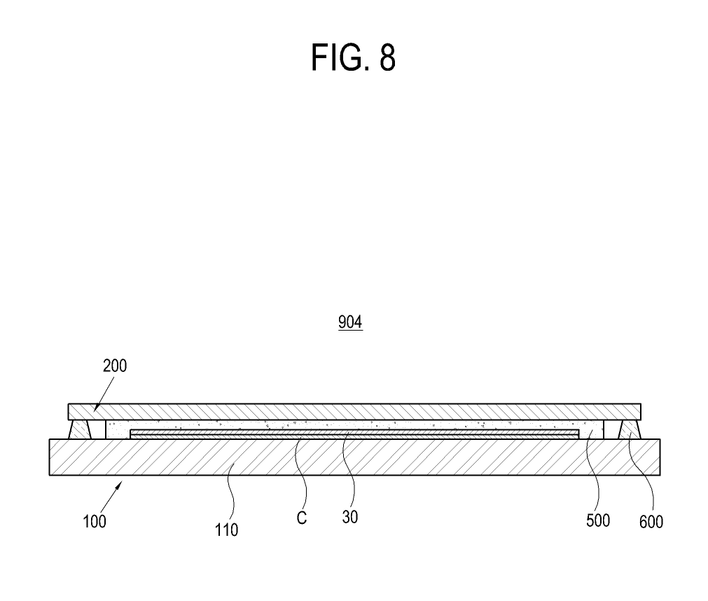

Referring to FIG. 8, the fourth exemplary embodiment of the present invention will be described.

As shown in FIG. 8, the display device 904 includes a barrier member 600 interposed between a display panel 100 and a sealing metal foil 200 and surrounding the organic light emitting diode 30.

The barrier member 600 may include a frit. A frit refers to material that is generally used for the manufacturing of glass. In detail, the frit may include a paste that is a mixture of ceramic materials, such as silicon dioxide and an organic binder. In the first exemplary embodiment, the frit may further include a transition metal such as iron (Fe), copper (Cu), vanadium (V), manganese (Mn), cobalt (Co), nickel (Ni), chrome (Cr), and neodymium (Nd). That is, the frit may be a multicomponent-glass doped with a transition metal.

The barrier member 600 surrounds the organic light emitting diode 30 and adheres to both the display panel 100 and the sealing metal foil 200. Accordingly, the barrier member 600 may cover the organic light emitting diode 30. That is, the organic light emitting diode 30 may be sealed by both of the sealant 500 and the barrier member 600.

With the above-described configuration, the display device 904 may more effectively prevent moisture from permeating the organic light emitting diode 30.

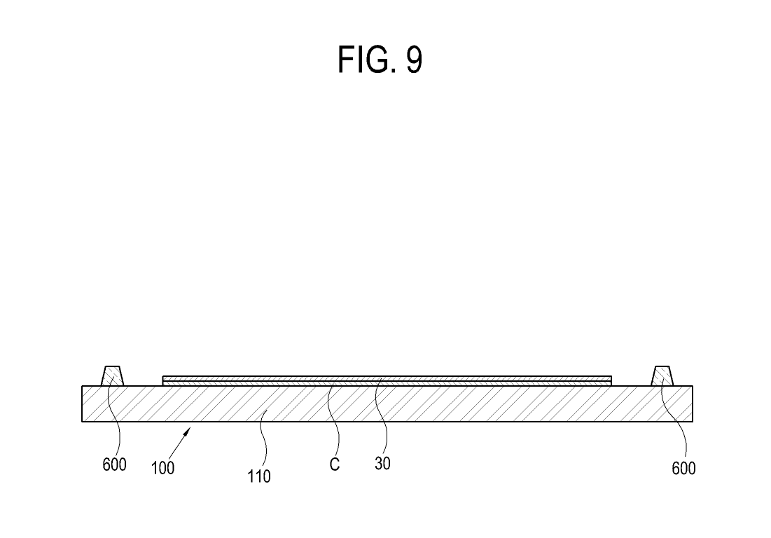

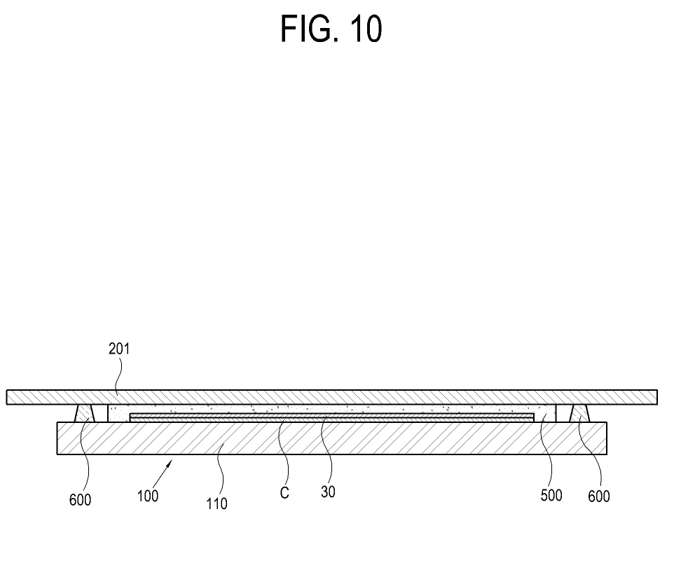

A method of manufacturing a display device 904 according to the fourth exemplary embodiment of the present invention will be described in detail with reference to FIG. 9 to FIG. 10.

As shown in FIG. 9, a barrier member 600 is formed on the display panel 100 to surround an organic light emitting diode 30.

The barrier member 600 may be formed thorough coating melted frit on the periphery of the display panel 100. The melted frit may be incompletely hardened by heating it to a temperature ranging from 200° C. to 500° C. That is, the barrier member 600 may not be completely hardened when it is being coated on the display panel 100, but may later harden to have a stable shape. In this process, unnecessary organic material and impurities may be removed from the barrier member 600. The melted frit may be coated along the periphery of the display panel 100 using a dispensing method or a screen printing method.

Then, as shown in FIG. 10, the sealant 500 covering the organic light emitting diode 30 of the display panel 100 may be formed, and a thin metal plate 201 covering the sealant 500 may be formed. Then, a sealing metal foil 200 may be formed thorough cutting the thin metal plate 201. Here, the thin metal plate 201 may be cut using the etchant. The barrier member 600 contacts the periphery of the sealing metal foil 200.

Then, the barrier member 600 may be completely hardened by providing an energy source. Herein, the energy source may be laser and/or heat. In this process, the barrier member 600 may adhere to the sealing metal foil 200.

As above shown in FIG. 8, the display device 904 according to the fourth exemplary embodiment of the present invention is formed.

With the above-described manufacturing method, the display device 904 may efficiently prevent moisture from permeating through the organic light emitting diode 30.

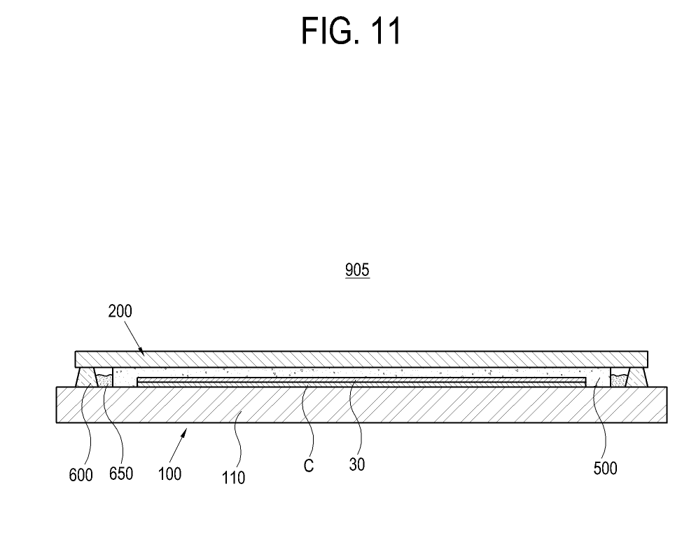

Referring to FIG. 11, the fifth exemplary embodiment of the present invention will be described.

As shown in FIG. 11, the display device 905 further includes a desiccant member 650 disposed between a barrier member 600 and an organic light emitting diode 30.

The desiccant member 650 may be made by coating a liquid desiccant, drying the coated liquid desiccant, and activating the dried liquid desiccant. The liquid desiccant may be dried and activated by providing an energy source. Herein, the liquid desiccant may be, for example, “DRYLOS®” of DuPont Company, U.S. The liquid desiccant may be coated through a dispensing method or a screen printing method. The energy source may be a laser and/or heat.

With the above-described configuration, the display device 905 may efficiently prevent moisture from permeating the organic light emitting diode 30.

A method of manufacturing the display device 905 according to the fifth exemplary embodiment of the present invention further includes forming the desiccant member 650 between the barrier member 600 and the organic light emitting diode 30.

The desiccant member 650 may be coated between the barrier member 600 and the organic light emitting diode 30 after the barrier member 600 is formed along the periphery of the display panel 100.

In other exemplary embodiments, the desiccant member 650 may be coated between the barrier member 600 and the organic light emitting diode 30 after or before covering the organic light emitting diode 30 with the sealant 500.

The energy source may activate the desiccant member 650 and harden the barrier member 600 at the same time.

As described above, according to exemplary embodiments of the present invention, the total size of the display device may be minimized.

That is, a thin sealing metal foil having a relatively small thickness may prevent moisture from permeating thorough the organic light emitting diode. Accordingly, the display device may be slim. Also, the cost of the display device may become low and productivity may be improved.

In addition, the display device may efficiently prevent moisture from permeating through the organic light emitting diode.

In addition, the above-described method of manufacturing the display device may be provided.

It will be apparent to those skilled in the art that various modifications and variations can be made in the present invention without departing form the spirit or scope of the invention. Thus, it is intended that the present invention cover the modifications and variations of this invention provided they come within the scope of the appended claims and their equivalents

What is claimed is:

1. A display device, comprising:
a display panel comprising an organic light emitting diode;
a sealing metal foil covering a side of the display panel on which the organic light emitting diode is disposed;
a sealant between the display panel and the sealing metal foil.

2. The display device of claim 1, wherein the sealing metal foil comprises a metal containing at least one of stainless steel, aluminum (Al), copper (Cu), molybdenum (Mo), silver (Ag), tantalum (Ta), tungsten (W), and titanium (Ti).

3. The display device of claim 2, wherein the sealing metal foil has a thickness of about 5 μm to about 500 μm.

4. The display device of claim 3, wherein the size of the sealing metal foil is substantially equal to or smaller than the size of the display panel.

5. The display device of claim 1, further comprising an overcoat layer interposed between the organic light emitting diode and the sealant.

6. The display device of claim 5, wherein the overcoat layer comprises inorganic material.

7. The display device of claim 1, further comprising a barrier member interposed between the display panel and the sealing metal foil, the barrier member surrounding the periphery of the organic light emitting diode.

8. The display device of claim 7, wherein the barrier member comprises frit.

9. The display device of claim 8, further comprising a desiccant member disposed between the barrier member and the organic light emitting diode.

10. A display device manufacturing method, comprising:
preparing a display panel comprising an organic light emitting diode (OLED);
coating a sealant on the organic light emitting diode;
covering the sealant with a thin metal plate;
forming a sealing metal foil covering the organic light emitting diode by cutting the thin metal plate.

11. The display device manufacturing method of claim 10, wherein the sealing metal foil comprises a metal containing at least one of stainless steel, aluminum (Al), copper (Cu), molybdenum (Mo), silver (Ag), tantalum (Ta), tungsten (W), and titanium (Ti).

12. The display device manufacturing method of claim 11, wherein the sealing metal foil has a thickness of about 5 μm to about 500 μm.

13. The display device manufacturing method of claim 11, wherein the thin metal plate is cut using an etchant.

14. The display device manufacturing method of claim 13, wherein cutting the thin metal plate comprises spreading the etchant over an etching place of the thin metal plate.

15. The display device manufacturing method of claim 14, wherein the etching place of the thin metal plate comprises a guide groove.

16. The display device manufacturing method of claim 10, further comprising forming a barrier member that surrounds the periphery of the organic light emitting diode before covering the sealant with the thin metal plate.

17. The display device manufacturing method of claim 16, further comprising forming a desiccant member between the barrier member and the organic light emitting diode.

18. The display device manufacturing method of claim 17, further comprising activating the desiccant member using an energy source.

19. The display device manufacturing method of claim 16, further comprising:
hardening the barrier member by providing an energy source; and
joining the barrier member to the sealing metal foil after covering the sealant with the thin metal plate.

20. The display device manufacturing method of claim 19, wherein the energy source comprises at least one of a laser and heat.
